(19) United States
(12) Patent Application Publication
(10) Pub. No.: US 2006/0261425 A1
(43) Pub. Date: Nov. 23, 2006

(54) Magnetic memory and method of manufacturing the memory

(75) Inventors: Katsumi Suemitsu, Tokyo (JP); Kuniko Kikuta, Tokyo (JP)

Correspondence Address: YOUNG & THOMPSON, 745 SOUTH 23RD STREET, 2ND FLOOR, ARLINGTON, VA, 22202, US

(73) Assignee: NEC CORPORATION, Tokyo (JP)

(21) Appl. No.: 10/529,851

(22) PCT Filed: Sep. 19, 2003
(86) PCT No.: PCT/JP03/11956

§ 371 Date: Mar. 31, 2005

(30) Foreign Application Priority Data
Oct. 2, 2002 (JP) 2002-290448

(51) Int. Cl. H01L 43/00

(52) U.S. Cl. 257/421

(57) ABSTRACT

A magnetic memory includes a substrate, a lower portion structure of a magnetic element, an upper portion structure of the magnetic element, and a sidewall insulating film. The lower portion structure of the magnetic element is a portion of the magnetic element provided on the upside of the substrate. The upper portion structure of the magnetic element is a remaining portion of the magnetic element provided on the upside of the lower portion structure of the magnetic element. The sidewall insulating film is provided to surround the upper portion structure of the magnetic element and is formed of an insulating material. That is, the lower portion structure of the magnetic element is formed from one layer or a plurality of layers on a side close to the substrate, among a plurality of laminated films of the magnetic element provided on the upside of the substrate. The upper portion structure of the magnetic element is formed from layers other than the lower portion structure of the magnetic element among the plurality of laminated films of the magnetic element. Also, the side of the upper portion structure of the magnetic element is electrically insulated from other portions by the sidewall insulating film. That is, it is possible to avoid a short-circuit.

### TECHNICAL FIELD

The present invention relates to a magnetic memory and a manufacturing method of the same, particularly, to a magnetic memory for storing data in nonvolatile manner by using spontaneous magnetization of a ferromagnetic material and a manufacturing method of the same.

### BACKGROUND ART

A magnetic memory (Magnetic Random Access Memory: hereinafter, to be referred to as MARM) is known as one of memories for storing data in nonvolatile manner. A magnetic element used for the MRAM has a structure having a non-magnetic layer between ferromagnetic layers. The magnetic element shows a different resistance value in accordance with the fact that the magnetization vectors of the upper and lower ferromagnetic layers are parallel or anti-parallel. The different resistance value can be related to “1” or “0”. By detecting the resistance value of the magnetic element, it is possible to read the data written in the magnetic element.

An MRAM is known which uses a giant magnetic resistance (hereinafter, to be referred to as “GMR”) effect and a tunnel magnetic resistance (hereinafter, to be referred to as “TMR”) effect. Hereinafter, the memory cell of an MRAM using the GMR effect is referred to as a GMR cell and the memory cell of an MRAM using the TMR effect is referred to as a TMR cell. The GMR cell has a conductive film of Cu or Cr as a non-magnetic layer, and the TMR cell has an insulating film of alumina or the like as a non-magnetic layer. In case of the TMR cells, magnetic elements are arranged in an array. A write operation of data in the magnetic element is carried out by using a magnetic field which is generated by a current flowing through a wiring nearby the magnetic element. Also, a read operation of data from the magnetic element is carried out by detecting the resistance value between electrodes provided in upside and downside of the magnetic element.

The magnetic element for the TMR cell has an insulating film like alumina as a non-magnetic layer. A read current flows in the direction vertical to a film surface through the non-magnetic layer. Therefore, if a conductive material is attached to the side of the magnetic element in a step of etching the magnetic element, a read current does not pass through the insulating film serving as the non-magnetic layer but it passes through the conductive material. As a result, the resistance value between electrodes at the both ends of the magnetic element is greatly decreased. This is referred to as a short-circuit. When such a short-circuit occurs, it is impossible to obtain sufficient characteristics as an MRAM.

To process the magnetic element, physical etching such as ion milling or physical chemical etching such as reactive ion etching (hereinafter, to be referred to as “RIE”) is used. When the physical etching such as the ion milling etching is used, it is confirmed that the number of short-circuited elements increases when the etching is carried out up to a portion deeper than a ferromagnetic layer to be first etched and a non-magnetic layer. Also, when RIE is used and the etching time is long, it is confirmed that an etching gas chemically reacts with the ferromagnetic layer and the magnetic characteristic of the ferromagnetic layer is deteriorated.

A technique is requested which can avoid a short-circuit caused because a conductive substance attaches to the side of a magnetic element when the magnetic element is formed by using the etching method. Also, a technique is requested which can restrain deterioration of the magnetic characteristic of a magnetic element when the magnetic element is formed by using the etching method. When a magnetic element is formed by using an etching method, a technique is requested which can process the whole of magnetic element through a once patterning step.

In conjunction with the above description, a magnetic memory is disclosed in U.S. Pat. No. 6,297,983B1 (Manoj Bhattacharyya). In the magnetic memory of this conventional example, the area of an active layer (free magnetized layer) is made smaller than that of a reference layer (fixed magnetized layer). Thereby, magnetization of the active layer (free magnetized layer) is stabilized. FIGS. 1A to 1D show a structure and a manufacturing method of the magnetic memory disclosed in this conventional example. The magnetic memory of this conventional example is manufactured as described below.

First, as shown in FIG. 1A, films (a conductive film 102′, a third ferromagnetic film 104′, an anti-ferromagnetic film 106′, a first ferromagnetic film 154′, an insulating film 152′, a second ferromagnetic film 150′, a cap film 114′, and a mask 120′) are sequentially deposited on a substrate 100. Then, as shown in FIG. 1B, the mask 120′ is patterned to a mask 120 to have a shape coincident with that of a magnetic element. Subsequently, the above films are etched by the ion milling method to have the pattern shape. Thereby, a conductive layer 102, a third ferromagnetic layer 104 (ferromagnetic seed layer), an anti-ferromagnetic layer 106, a first ferromagnetic layer 154 (fixed magnetized layer), an insulating layer 152, a second ferromagnetic layer 150 (free magnetized layer), a cap layer 114, and a mask 120 are formed on the substrate 100 (second step). Then, as shown in FIG. 13C, the mask 120 is patterned to a mask 120″ to have a shape coincident with that of a broken line 126. Then, etching is carried out by using an ion milling method so that the area of the second ferromagnetic layer (free magnetized layer) 150 becomes smaller than that of the first ferromagnetic layer (fixed magnetized layer) 154. Thus, an etching-scheduled shape 126 is obtained (third step). That is, the etching is carried out by using the pattern (mask 120), for the downsizing the magnetic element, and then the upside of the magnetic element is etched by using another pattern (mask 120″) by the ion milling method.

When the magnetic element is etched by using ion milling, the result of the second step may become the state shown in FIG. 1D instead of the state shown in FIG. 1B. That is, particles of the sputtered film are attached to the side of the magnetic element and the mask 120 to form a side attachment 125. For this reason, when the etching is carried out in the third step to make the area of the second ferromagnetic layer 150 (free magnetized layer) smaller than that of the first ferromagnetic layer 154 (fixed magnetized layer), the interval between the mask 120″ and the side attachment 125 is decreased unless a difference between the size of the mask 120″ and that of the lower portion (anti-ferromagnetic layer 106 or the like) of the magnetic element is so large. Thus, particles produced during the ion milling do not enter the space between them so that etching cannot accurately be made according to an etching planned shape 126.

Japanese Laid Open Patent Application (JP-P2002-124717) discloses a magnetic thin film memory using a magnetic resistance effect element. The magnetic resistance effect element of this conventional example has a magnetic tunnel junction in which a first magnetic layer, a tunnel barrier layer, and a second magnetic layer are sequentially laminated. The tunnel barrier layer is formed of thin insulating material. A tunnel current flows between the first magnetic layer and the second magnetic layer through the tunnel barrier layer. A compound layer and an insulating layer are arranged to restrict the region of the second magnetic layer where the tunnel current flows. The compound layer is formed of oxide or nitride of a material of the second magnetic layer. The insulating layer is formed of an insulating material on the compound layer.

Japanese Laid Open Patent Application (JP-A-Heisei 10-4227) discloses a magnetic tunnel junction capable of controlling a magnetic response. The magnetic tunnel junction element of the conventional example includes a substrate, a first electrode, a second electrode, and an insulating tunnel layer. The first electrode has a fixed ferromagnetic layer and anti-ferromagnetic layer. The fixed ferromagnetic layer is formed on the substrate and flat. The anti-ferromagnetic layer is adjacent to the fixed ferromagnetic layer to fix the magnetized direction of the fixed ferromagnetic layer in a preferred direction and prevents the reversion of magnetization direction under an applied magnetic field. The second electrode has a flat free ferromagnetic layer capable of freely reversible in the magnetized direction under the applied magnetic field. The insulating tunnel layer is provided between the fixed ferromagnetic layer and the free ferromagnetic layer to allow a tunnel current to flow in the direction vertical to the fixed ferromagnetic layer and free ferromagnetic layer. The insulating tunnel layer has a side circumference to prevent the fixed ferromagnetic layer or free ferromagnetic layer from extending, exceeding the side circumference of the insulating tunnel layer. Moreover, the insulting tunnel layer is held in another plane in which the fixed ferromagnetic layer and free ferromagnetic layer are separate from each other without overlapping.

Japanese Laid Open Patent Application (JP-a-Heisei 11-330585) discloses a magnetic function element and a variable resistance element. The magnetic function element of the conventional example has a laminated body. In case of the laminated body, a conductive layer including a conductive material and a plurality of magnetic layers are laminated so that the conductive layer is located between the magnetic layers. By supplying a current to the conductive layer of the laminated body, a magnetic coupling state between the magnetic layers is changed to control the magnetization direction of the magnetic layers.

Japanese Laid Open Patent Application (JP-P2002-9367) discloses a magnetic memory using a ferromagnetic tunnel effect element. The ferromagnetic tunnel effect element of the conventional example has a laminated structure in which two ferromagnetic layers are located to face each other through a tunnel barrier layer. A tunnel current flowing through the tunnel barrier layer changes depending on the relative relation of the magnetization directions of the two ferromagnetic layers. The tunnel barrier layer is formed of amorphous material, polycrystalline material, or single crystalline material having no perovskite structure. Moreover, at least one of the two ferromagnetic layers is formed of a perovskite oxide magnetic substance which is oriented only in one axial direction.

### DISCLOSURE OF INVENTION

Therefore, an object of the present invention is to provide a magnetic memory structure and a manufacturing method, in which magnetic elements having a desired performance can be manufactured in a high yield when the magnetic elements are formed by using an etching method.

Also, another object of the present invention is to provide a magnetic memory structure and a manufacturing method, in which generation of a short-circuit can be prevented when a magnetic element is formed by using an etching method.

Still another object of the present invention is to provide a magnetic memory structure and a manufacturing method, in which deterioration of the magnetic characteristic of a magnetic element can be restrained when the magnetic element is formed by using an etching method.

It is still another object of the present invention to provide a magnetic memory and a manufacturing method, in which a magnetic element can be inexpensively manufactured with a few number of steps when the magnetic element with less generation of a short-circuit and less deterioration of a magnetic characteristic is manufactured by using an etching method.

Therefore, in an aspect of the present invention, a magnetic memory includes a substrate, a lower portion structure of a magnetic element, an upper portion structure of the magnetic element, and a sidewall insulating film. The lower portion structure of the magnetic element is a portion of the magnetic element provided on the upside of the substrate. The upper portion structure of the magnetic element is a remaining portion of the magnetic element provided on the upside of the lower portion structure of the magnetic element. The sidewall insulating film is provided to surround the upper portion structure of the magnetic element and is formed of an insulating material. That is, the lower portion structure of the magnetic element is formed from one layer or a plurality of layers on a side close to the substrate, among a plurality of laminated films of the magnetic element provided on the upside of the substrate. The upper portion structure of the magnetic element is formed from layers other than the lower portion structure of the magnetic element among the plurality of laminated films of the magnetic element. Also, the side of the upper portion structure of the magnetic element is electrically insulated from other portions by the sidewall insulating film. That is, it is possible to avoid a short-circuit.

Also, in the magnetic memory of the present invention, the magnetic element has a size specified by the outer circumference of the sidewall insulating film. Thus, the magnetic element has a size of (the upper portion structure of the magnetic element+thickness of the sidewall insulating film). It is possible to avoid the short-circuit without increasing the size of the magnetic element.

Also, in case of the magnetic memory of the present invention, the lower portion structure of the magnetic element may include a conductive portion and a first magnetic film provided on the upside of the conductive portion. Also, the upper portion structure of the magnetic element may include an insulating film and a second magnetic film provided on the upside of the insulating film.

Also, in case of the magnetic memory of the present invention, the lower portion structure of the magnetic element may include a conductive portion. The upper portion structure of the magnetic element may include a first magnetic film, an insulating film formed on the upside of the first magnetic film, and a second magnetic film provided on the upside of the insulating film. Also, in case of the magnetic memory of the present invention, the upper portion structure of the magnetic element may further include a conductive film formed on the upside of the second magnetic film.

Also, in case of the magnetic memory of the present invention, the shape of the upper portion structure of the magnetic element is any one of an oval, a cycloid, a rectangle, a hexagon, and a corner quadrangle, Also, in case of the magnetic memory of the present invention, the distance d on a plane between the outer circumference of the upside of the lower portion structure of the magnetic element and the outer circumference of the upside of the upper portion structure of the magnetic element has a relation of 0.01 m≦d≦0.2 m.

Also, the magnetic memory of the present invention may be further provided with an interlayer insulating film formed to cover the lower portion structure of the magnetic element, the sidewall insulating film, and the upper portion structure of the magnetic element. In this case, the interlayer insulating film may have a via-hole on the upside of the upper portion structure of the magnetic element. The sidewall insulating film is formed of a material which has an etching selection ratio to the interlayer insulating film smaller than the interlayer insulating film.

Also, the magnetic memory of the present invention may be further provided with a lower portion structure of the magnetic element and an interlayer insulating film formed to cover the sidewall insulating film. In this case, the interlayer insulating film may be flattened in the upside of the magnetic element by a chemical mechanical polishing method or an etching-back method after being formed to cover the lower portion structure of the magnetic element, the sidewall insulating film, and the upper portion structure of the magnetic element. The sidewall insulating film may be formed of a material which has a selection ratio in the chemical mechanical polishing method or the etching-back method smaller than the interlayer insulating film.

Also, in case of the magnetic memory of the present invention, the sidewall insulating film may be formed of at least one of metal nitride, metal oxide, and metal carbide. Further, in case of the magnetic memory of the present invention, the sidewall insulating film may include at least one of silicon oxide, silicon nitride, aluminum oxide, and aluminum nitride.

Also, in another aspect of the present invention, a magnetic memory manufacturing method forms a multi-layer film included in a magnetic element on the upside of a substrate, etches the multi-layer film into a predetermined pattern up to a predetermined depth, forms the upper portion structure of the magnetic element as a part of the magnetic element, forms the sidewall insulating film to surround the upper portion structure of the magnetic element, etches the multi-layer film by using the sidewall insulting film and the upper portion structure of the magnetic element as a mask, and forms the lower portion structure of the magnetic element as a remaining portion of the magnetic element.

Also, in case of the magnetic memory manufacturing method of the present invention, the lower portion structure of the magnetic element may include a first magnetic layer formed on a conductive portion and the upside of the conductive portion. The upper portion structure of the magnetic element may include an insulting layer and a second magnetic layer formed on the upside of the insulating layer.

Also, in case of the magnetic memory manufacturing method of the present invention, the etching is carried out into a predetermined pattern by using a physical etching method. Also, it is preferable that the physical etching method is an ion milling method.

Also, the lower portion structure of the magnetic element may include a conductive portion, and the upper portion structure of the magnetic element may include the first magnetic layer, an insulating layer formed on the upside of the first magnetic layer, and the second magnetic layer formed on the upside of the insulating layer. The multi-layer film may be etched by using a physical chemical etching method. Moreover, the physical and chemical etching is a reactive ion etching method.

Also, in case of the magnetic memory manufacturing method of the present invention, an interlayer insulating film is formed to cover the lower portion structure of the magnetic element, the sidewall insulating film, and the upper portion structure of the magnetic element, and a via-hole is formed in the interlayer insulating film on the upside of the upper portion structure of the magnetic element by an etching. The sidewall insulating film is formed of a material which has an etching selection ratio to the interlayer insulating film is smaller than 1.

Also, in case of the magnetic memory manufacturing method of the present invention, an interlayer insulating film is formed to cover the lower portion structure of the magnetic element, the sidewall insulating film, and the upper portion structure of the magnetic element, and the interlayer insulating film on the upside of the upper portion structure of the magnetic element is flattened through a chemical mechanical polishing method or an etching-back method. The sidewall insulating film is formed of a material which has a selection ratio to the interlayer insulating film in the chemical mechanical polishing or etching-back is smaller than 1.

### BRIEF DESCRIPTION OF DRAWINGS

FIGS. 1A to 1D are cross sectional views showing a configuration and a manufacturing method of a conventional magnetic memory;

FIGS. 2A to 2F are cross sectional views showing a method of manufacturing a magnetic memory according to a first embodiment of the present invention;

FIGS. 3A to 3F are cross sectional views showing the method of manufacturing the magnetic memory according to a second embodiment of the present invention;

FIGS. 4A to 4F are cross sectional views showing the method of manufacturing the magnetic memory according to a third embodiment of the present invention;

FIGS. 5A to 5E are cross sectional views showing the method of manufacturing the magnetic memory according to a fourth embodiment of the present invention;

FIGS. 6A to 6G are cross sectional views showing the method of manufacturing the magnetic memory according to a fifth embodiment of the present invention;

FIGS. 7A to 7F are cross sectional views showing the method of manufacturing the magnetic memory according to a sixth embodiment of the present invention;

FIGS. 8A to 8C are plan vies showing a relation between an upper portion of the magnetic element, a sidewall, and a lower portion of the magnetic element;

FIGS. 9A to 9C are cross sectional views showing steps of flattening a layer insulating layer; and

FIGS. 10A to 10C are cross sectional views showing steps of forming a via-hole on the layer insulating layer.

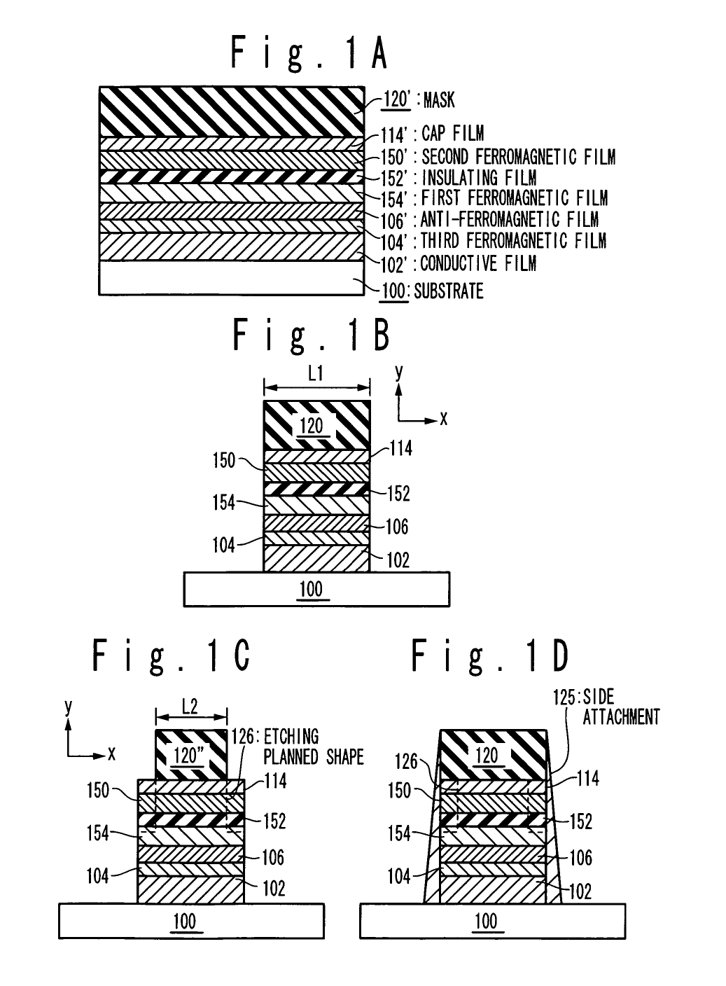

### BEST MODE FOR CARRYING OUT THE INVENTION

Hereinafter, a magnetic memory and a manufacturing method of it according to the present invention will be described with reference to the attached drawings. In the following description, the same or equivalent portion is provided with the same reference numeral.

### First Embodiment

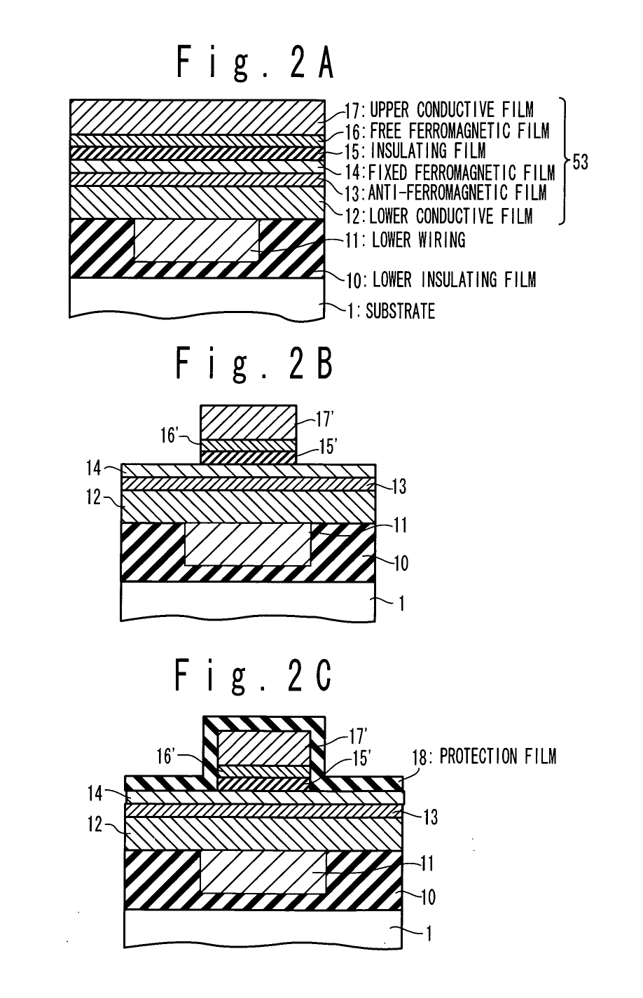

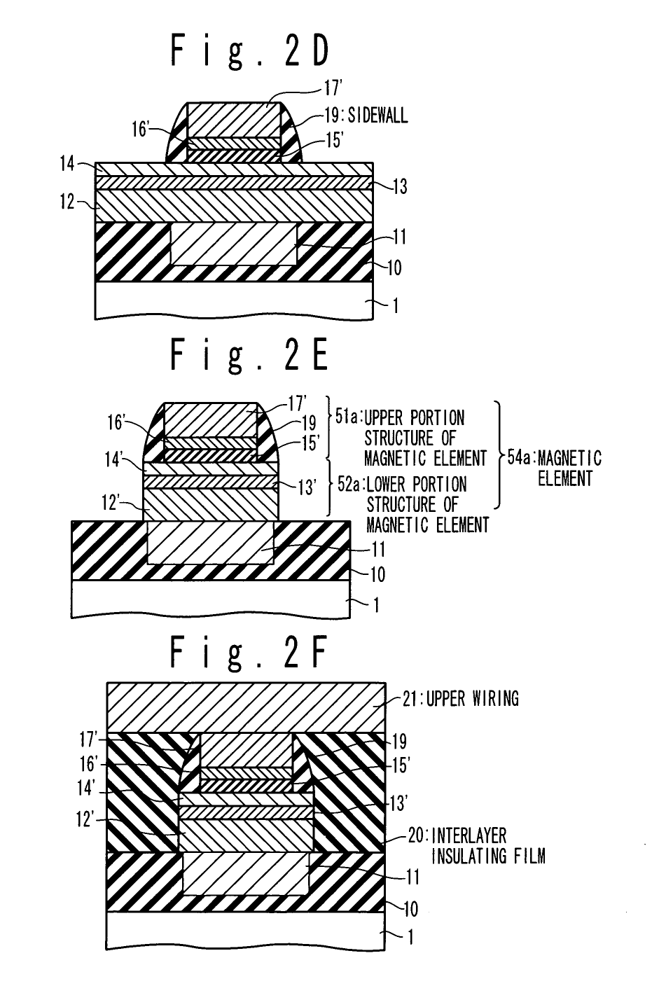

The magnetic memory according to the first embodiment of the present invention and the manufacturing method of the same will be described below. FIGS. 2A to 2F are cross sectional views showing the method of manufacturing the magnetic memory according to the first embodiment of the present invention. The magnetic memory manufacturing method in this embodiment is a method of manufacturing a TMR cell. The magnetic element serving as the TMR cell is formed on a wiring layer of copper or the like which is formed on a CMOS circuit. FIGS. 2A to 2F show steps of manufacturing the magnetic element on a lower wiring 11 made of copper or the like.

First, as shown in FIG. 2A, the lower wiring 11 (e.g., of copper) for write and read is formed in a lower insulating layer 10 (e.g., formed from a silicon oxide film) which is formed on a substrate 1 (e.g., of silicon) by using a damascene process. A multi-layer film 53 for a TMR structure is formed on the lower wiring 11. That is, a lower conductive film 12, an anti-ferromagnetic film 13, a fixed ferromagnetic film 14, an insulating film 15, a free ferromagnetic film 16, and an upper conductive film 17 are sequentially formed from the lower wiring 11. Each of the lower conductive film 12 and the upper conductive film 17 is a single-layer film or a multi-layer film including a conductive material such as copper, aluminum, tantalum, titanium nitride, and permalloy (NiFe).

In this embodiment, the lower conductive film 12 is a multi-layer film of a titanium nitride film, a tantalum film, an aluminum film, a tantalum film, and a permalloy (NiFe) film which are sequentially laminated. The upper conductive film 17 is a titanium nitride film. The thickness of each of the films 12 and 17 is approximately 50 nm. The anti-ferromagnetic film 13 is formed of an anti-ferromagnetic material such as platinum manganese (PtMn), iridium manganese (IrMn), iron manganese (FeMn), and nickel manganese (NiMn). In this embodiment, the anti-ferromagnetic film 13 is formed from an iron manganese (FeMn) film. The film thickness thereof is approximately 30 nm. The fixed ferromagnetic film 14 and the free ferromagnetic film 16 are formed of a ferromagnetic material such as permalloy (NiFe), iron cobalt (FeCo), iron nickel cobalt (NiFeCo), or cobalt. In this embodiment, the fixed ferromagnetic film 14 and the free ferromagnetic film 16 are formed from permalloy (NiFe) films. The insulating film 15 is formed of an insulating material such as alumina (Al₂O₃) and hafnium oxide. In this embodiment, the insulating film 15 is formed from an alumina (Al₂O₃) film, which is formed by applying plasma oxidation to an Al film. The thickness of the insulating film 15 is approximately 1.5 nm and is very thin to an extent that a tunnel current flows through the insulating film 15. Moreover, a sum of thicknesses of the fixed ferromagnetic layer 14, the insulating film 15, and the free ferromagnetic film 16 is as very small as approximately 30 nm or less.

Next, as shown in FIG. 2B, an upper portion structure 51a of the magnetic element is formed. In this case, a photo-resist layer is formed in a predetermined pattern and etching is carried out by an ion milling method by using the resist pattern as a mask. The etching is carried out up to the boundary between the insulating film 15 and the fixed ferromagnetic film 14. Then, the photo-resist layer is removed. Through this etching, an upper conductive layer 17′ of the magnetic element, a free ferromagnetic layer 16′ serving as a second magnetic layer, and an insulating layer 15′ are formed. In this embodiment, the upper conductive layer 17′, the free ferromagnetic layer 16′, and the insulating layer 15′ are also referenced to as the upper portion structure 51a of the magnetic-element. The above predetermined shape is the shape of the upper portion structure 51a of the magnetic-element.

Next, as shown in FIG. 2C, a sidewall 19 serving as a sidewall is formed. First, a protection film 18 is formed to cover the fixed ferromagnetic film 14 and the upper portion structure 51a of the magnetic element. The protection film 18 is formed of an insulating material such as oxide, nitride and carbide film of metal. For example, the film 18 is formed from a silicon oxide film, a silicon nitride film, an aluminum oxide film, or an aluminum nitride film. In this embodiment, the protection film 18 is the silicon nitride film. Because the protection film 18 has an insulating characteristic, it does not influence electrical characteristics of the free ferromagnetic layer 16′ and insulating layer 15′.

Next, as shown in FIG. 2D, dry etching is applied to the protection film 18 under a predetermined condition and the sidewall 19 is formed. The predetermined condition is experimentally determined in accordance with the structure of the magnetic element or the characteristic of the protection film 18. Thereby, the sides of the upper conductive layer 17′, the free ferromagnetic layer 16′, and the insulting layer 15′ are not exposed to an etching atmosphere in the later etching steps. Therefore, it is possible to avoid deterioration of film quality due to etching gas, attachment of an etched substance to the side (side attachment), or and abnormal electrical characteristic due to the attachment in the substance of the free ferromagnetic layer 16′ and the insulting layer 15′.

Next, as shown in FIG. 2E, a lower portion structure 52a of the magnetic element is formed. Etching is carried out up to the bottom of the lower conductive film 12 by using the sidewall 19 and the upper conductive layer 17′ as a mask. The ion milling method is used as an etching method. This etching is carried out up to the boundary between the lower wiring 11 and the lower conductive film 12. Through this etching, a fixed ferromagnetic layer 14′, an anti-ferromagnetic layer 13′, and a lower conductive layer 12′, which serve as a first magnetic layer, are formed in self-aligned manner. In this embodiment, the fixed ferromagnetic layer 14′, the anti-ferromagnetic layer 13′, and the lower conductive layer 12′ are also referenced to as the lower portion structure 52a of the magnetic element. Because etching is carried out by using the sidewall 19 and the upper conductive layer 17′ as a mask, steps relating to photolithography are unnecessary. That is, although etching is carried out two times to form the upper portion structure 51a and the lower portion structure 52a for the magnetic element, a step of photolithography is carried out only once and it is possible to restrain increase of the number of steps.

Next, as shown in FIG. 2F, an interlayer insulating film 20 is formed. First, the interlayer insulating film 20 is formed to cover the lower insulating layer 10, the lower portion structure 52a of the magnetic element, and the upper portion structure 51a of the magnetic element. The interlayer insulating film 20 is formed from a metal oxide film, a metal nitride film, a carbide film, or a conventionally known inorganic or organic low-permittivity insulating film. For example, a silicon oxide film, a silicon nitride film, an aluminum oxide film, or an aluminum nitride film is usable. In this embodiment, the interlayer insulating film 20 is a silicon oxide film. Then, the interlayer insulating film 20 is polished up to the surface of the upper conductive layer 17′ by a chemical mechanical polishing (CMP) method. Instead, an etching-back method may be used. In this case, CF₄ is used as an etching gas. It is possible to accomplish an accurate flattened surface although it takes a long time. As another method, the CMP method may be carried out and then the etching-back may be carried out. In this case, it is possible to accomplish quick and accurate flattening. Then, an upper wiring 21 is formed on the interlayer insulating film 20 as a write and read wiring.

The TMR cell is completed through the above steps.

In the magnetic memory manufacturing method of this embodiment, physical etching (e.g., ion milling) is used to form the upper portion structure 51a of the magnetic element. In this case, by stopping etching nearby the bottom of the insulating film 15 and covering the side of the upper portion structure 51a of the magnetic element with the sidewall 19, it is possible to decrease the short-circuit rate. Also, when the lower portion structure 52a of the magnetic element is formed through the etching, the sidewall 19 and the upper conductive layer 17′ are used as a mask. Thus, it is possible to form the magnetic element (upper portion structure 51a and the lower portion structure 52a of the magnetic element) through once patterning.

Moreover, it is possible to use RIE as a method for forming the upper portion structure 51a of the magnetic element. In this case, by stopping etching nearby the bottom of the insulating film 15 and covering the side of the upper portion structure 51a of the magnetic element with the sidewall 19, it is possible to decrease the time during which the side of the free ferromagnetic layer 16′ after etched is exposed to plasma, compared to a case of carrying out etching up to a portion deeper than the insulting film 15. Thus, it is possible to decrease the deterioration of the magnetic characteristic of the free ferromagnetic layer 16′. Also, only once patterning is required.

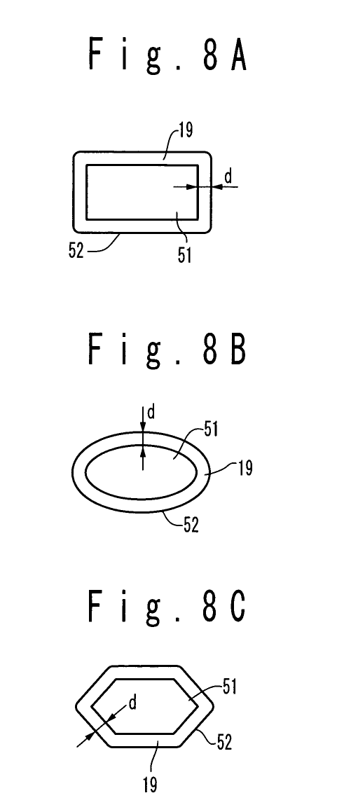

Further, in the magnetic memory manufacturing method of this embodiment, it is possible that the size of the lower portion structure 52a of the magnetic element is controlled to approximately (the upper portion structure 51a of the magnetic element+the thickness the sidewall 19). For example, to prevent characteristic deterioration of the magnetic element due to etching, the size of the lower portion structure 52a of the magnetic element may be increased compared to the size of the upper portion structure 51a of the magnetic element (U.S. Pat. No. 6,297,983 B1). In this case, the effect of restraint of deterioration of the magnetic element increases as the difference between sizes of the lower portion structure 52a of the magnetic element and the upper portion structure 51a of the magnetic element increases. Therefore, the size of the lower portion structure 52a of the magnetic element is made large. However, when the size of the lower portion structure 52a of the magnetic element is made too large, the number of magnetic elements for unit area decreases. In the magnetic memory manufacturing method of this embodiment, the lower portion structure 52a of the magnetic element is formed by the etching by using the sidewall 19 and the upper conductive layer 17′ as a mask. Therefore, the size of the lower portion structure 52a of the magnetic element can be controlled to (the upper portion structure 51a of the magnetic element+the thickness of the side wall 19) (protection film 18). This state is shown in FIGS. 8A to 8C.

FIGS. 8A to 8C are plan views showing the relation between the upper portion structure 51 of the magnetic element, the sidewall 19, and the lower portion structure 52 of the magnetic element. When the shape of the upper portion structure 51 of the magnetic element is supposed to be a rectangle A, ellipse B, or hexagon C, the lower portion structure 52 of the magnetic element is formed by etching by using the sidewall 19 and the upper conductive layer 17′ (upper portion structure 51 of the magnetic element) as a mask. In this case, the distance d between the outer periphery of the lower portion structure 52 of the magnetic element (upside) and the outer periphery of the upper portion structure 51 of the magnetic element (downside) becomes almost equal to the thickness of the sidewall 19 (protection film 18). Because control of the thickness of the protection film 18 is easy, control of the size of the lower portion structure 52a of the magnetic element is easy and it is possible to obtain a desired thickness. That is, it is possible to control the size of the lower portion structure 52a of the magnetic element to a proper size. In this case, it is preferable that the distance d ranges in 0.01 m≦d≦0.2 m. When the distance d is smaller than 0.01 m, it is difficult to form a sidewall having a high insulating characteristic (covering almost the whole of the side of the upper conductive layer 17′). When the distance d is larger than 0.2 μm m, the occupancy ratio of the magnetic element 54 on the substrate 1 increases and the integration density of the magnetic elements decreases.

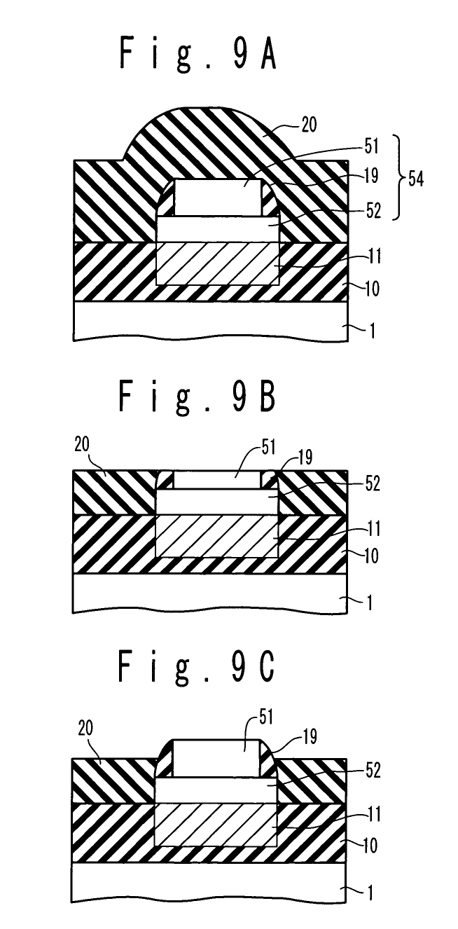

Moreover, in the magnetic memory manufacturing method of this embodiment, CMP and/or etching-back are or is applied to the interlayer insulating layer 20 so that the upper wiring 21 and upper conductive layer 17′ are electrically connected each other. By decreasing the selection ratio of the material of the sidewall 19 lower than to the interlayer insulating layer 20, it is possible to increase the production yield in CMP or etching-back. This is described by referring to FIGS. 9A to 9C.

FIGS. 9A to 9C are cross sectional views showing steps of flattening the interlayer insulating layer 20. These views show steps between FIGS. 2E and 2F. FIG. 9A is the cross sectional view after the interlayer insulating layer 20 is formed to cover the lower insulating film 10 and the magnetic element 54. In this case, when it is supposed that the interlayer insulating layer 20 and the sidewall 19 are made of the same material and CMP is carried out for a long time, the sidewall 19 and the upper conductive layer 17′ are similarly removed as shown in FIG. 9B. However, when the sidewall 19 is formed by a material having a selection ratio lower than that of the interlayer insulating layer 20, the sidewall 19 is not easily removed as shown in FIG. 9C. Therefore, the upper conductive layer 17′ is not easily removed because it is protected by the sidewall 19. As a result, even when the CMP method is carried out for a long time, the upper conductive layer 17′ is not excessively removed.

When a material having the selection ratio lower than that of the interlayer insulating layer 20 is used for the sidewall 19, combinations between the sidewall 19 and the interlayer insulating layer 20 are shown below.

A: Sidewall 19: Silicon oxide film/interlayer insulating layer 20 formed at 300° C. by using plasma CVD: Silicon oxide film formed at 400° C. by using the plasma CVD. In this case, even if the same film (silicon oxide film) is used, it is possible to set the selection ratio of CMP and/or etching-back to a desired value.

B: Sidewall 19: Laminated film of silicon oxide film and silicon oxide nitride film/interlayer insulating film 20: Silicon oxide film

C: Sidewall 19: Silicon oxide film/interlayer insulating layer 20: porous organic silica serving as low dielectric constant film

However, the present invention is not limited to the above examples A to C.

Moreover, in the magnetic memory manufacturing method of this embodiment, the interlayer insulating layer 20 is flattened by the CMP method to electrically connect the upper wiring 21 with the upper conductive layer 17′. However, it is also allowed to form a via-hole in the upper portion of the interlayer insulating layer 20 by etching and form the connection with the upper wiring 21 by using the via-hole.

It should be noted that the magnetic memory manufacturing method of this embodiment can be applied to formation of a GMR cell by forming a non-magnetic film formed of a conductive material which is an non-magnetic material like copper instead of the insulating film 15.

Moreover, this embodiment may be modified as long as the scope of the present invention is maintained.

### Second Embodiment

Then, the magnetic memory and its manufacturing method according to the second embodiment of the present invention will be described below.

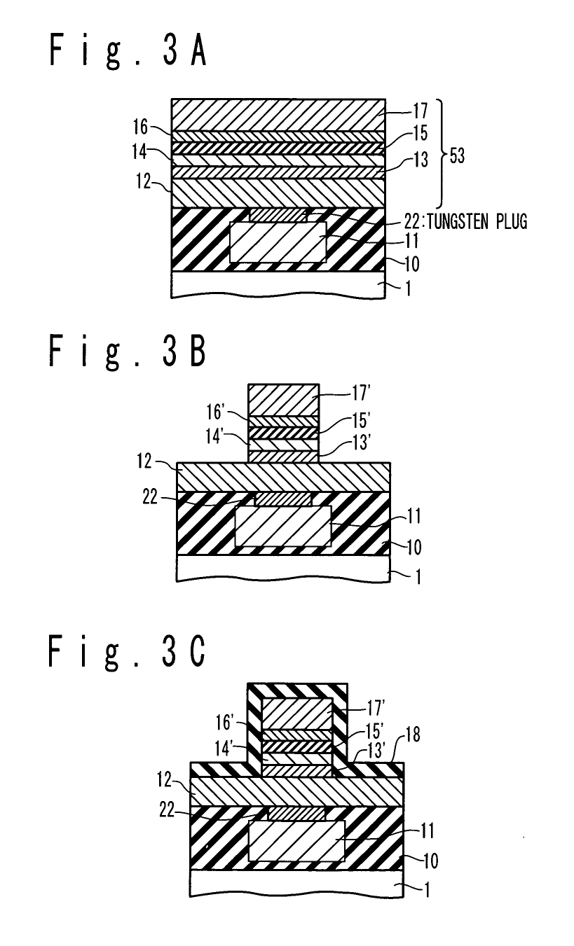

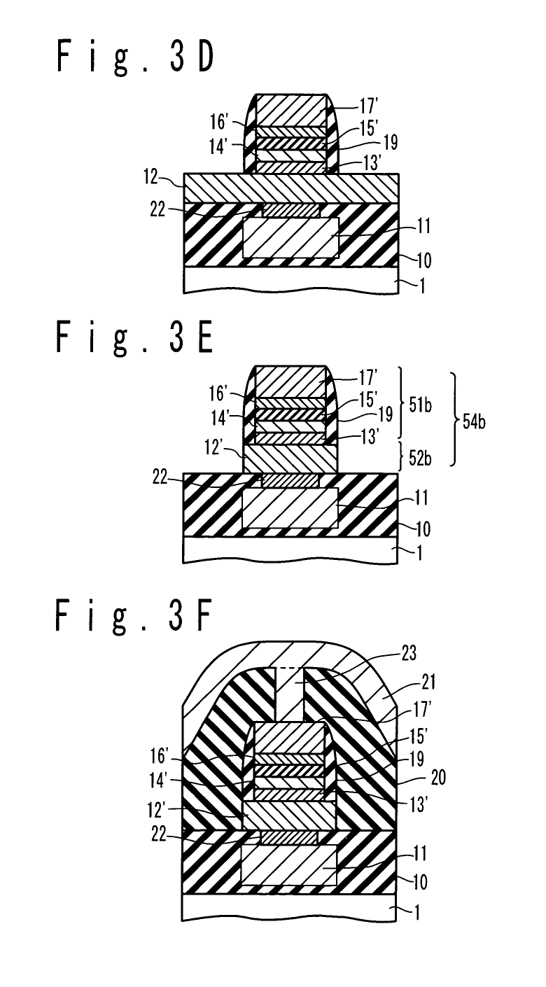

FIGS. 3A to 3F are cross sectional views showing a magnetic memory manufacturing method according to the second embodiment. The magnetic element manufacturing method of this embodiment is a method for manufacturing a TMR cell. The magnetic element serving as a TMR cell is formed on a via-contact made of tungsten (tungsten plug) for electrically connecting a wiring of copper or the like formed on a CMOS circuit with the magnetic element. FIGS. 3A to 3F show steps of forming the magnetic element on the tungsten plug 22 on the lower wiring 11 of copper aluminum (AlCu) or the like.

First, as shown in FIG. 3A, in the area for forming the magnetic element 54 on a lower insulating layer 10 (e.g., silicon oxide film) formed on a substrate 1 (e.g., silicon), the write and read lower wiring 11 and the tungsten plug 22 (e.g., copper aluminum (AlCu)) on the lower wiring 11 are formed by using a damascene process. Subsequently, a multi-layer film 53 having a TMR structure is formed on the wiring 11 and plug 22. That is, a lower conductive film 12, an anti-ferromagnetic film 13, a fixed ferromagnetic film 14, an insulating film 15, a free ferromagnetic film 16, and an upper conductive film 17 are sequentially formed from the tungsten plug 22 side. The films are the same as those of the first embodiment. In this embodiment, however, iridium manganese (IrMn) is used as the material of the anti-ferromagnetic film 13 and iron cobalt (CoFe) is used as the material of the fixed ferromagnetic film 14.

Next, as shown in FIG. 3B, an upper portion structure 51b of the magnetic element is formed. A photo-resist layer is patterned into a predetermined shape. Etching is carried out by using the resist pattern as a mask by a reactive ion etching (RIE) method. In this case, the etching is carried out up to the boundary between the anti-ferromagnetic film 13 and the lower conductive film 12. Subsequently, the photo-resist layer is removed. Through this etching, the upper conductive layer 17′ of the magnetic element, the free ferromagnetic layer 16′ serving as a second magnetic layer, the insulating layer 15′, the fixed ferromagnetic layer 14′ serving as a first magnetic layer, and the anti-ferromagnetic layer 13′ are formed. In this embodiment, the set of the upper conductive layer 17′, the free ferromagnetic layer 16′, the insulating layer 15′, the fixed ferromagnetic layer 14′, and the anti-ferromagnetic layer 13′ is referenced as the upper portion structure 51b of the magnetic element. The above predetermined shape is the shape of the upper portion structure 51b of the magnetic element.

Next, as shown in FIG. 3C, the sidewall 19 serving as a sidewall is formed. First, the protection film 18 is formed to cover the lower conductive film 12 and the upper portion structure 51b of the magnetic element. The protection film 18 is the same as the case of the first embodiment.

Next, as shown in FIG. 3D, the protection film 18 is dry-etched under a predetermined condition to form the sidewall 19. The predetermined condition is experimentally determined. Thus, the sides of the upper conductive layer 17′, free ferromagnetic layer 16′, insulating layer 15′, fixed ferromagnetic layer 14′, and anti-ferromagnetic layer 13′ are not exposed to the atmosphere of etching in the subsequent etching steps. Therefore, it is possible to avoid deterioration of qualities of the free ferromagnetic layer 16′ and the insulating layer 15′, attachment of an etched substance to the sides of the free ferromagnetic layer 16′ and the insulating layer 15′ (side attachment), and an abnormal electrical characteristic due to the attachment.

Next, as shown in FIG. 3E, the lower portion structure 52b of the magnetic element is formed. Etching is carried out up to the bottom of the lower conductive layer 12 by using the sidewall 19 and upper conductive layer 17′ as a mask. The reactive ion etching (RIE) is used as the etching method. This etching is carried out up to the boundary between the lower wiring 11 and the lower conductive film 12. The lower conductive layer 12′ is formed through the above etching. In this embodiment, the lower conductive layer 12′ is referenced to as the lower portion structure 52b of the magnetic element. Because the etching is carried out by using the sidewall 19 and the upper conductive layer 17′ as a mask, a step relating to photolithography is unnecessary. That is, to form the magnetic element, the etching is carried out two times for the upper portion structure 51b of the magnetic element and the lower portion structure 52b of the magnetic element. However, because a step of once photolithography is enough, it is possible to restrain the increase of the number of steps.

Next, as shown in FIG. 3F, an interlayer insulating film 20 is formed. First, the interlayer insulating film 20 is formed to cover the lower insulating layer 10, the lower portion structure 52b of the magnetic element, and the upper portion structure 51b of the magnetic element. The interlayer insulating film 20 is the same as that of the first embodiment. Subsequently, the patterning is carried out by using a photo-resist layer and then, the via-hole 23 is formed by dry etching. Then, the photo-resist layer is removed and the upper wiring 21 is formed in the via-hole 23 and on the interlayer insulating film 20 as the write and read wring.

The TMR cell is completed through the above steps.

In the magnetic memory manufacturing method of this embodiment, the RIE is used as a method for forming the upper portion structure 51b of the magnetic element. In this case, the etching is stopped in front of the lower conductive film 12 so that the etching time does not become too long. Thus, it is possible to restrain deterioration of qualities (including magnetic characteristic) of the free ferromagnetic layer 16′ and the fixed ferromagnetic layer 14′ due to etching.

Also, by covering the sides of the free ferromagnetic layer 16′ and the fixed ferromagnetic layer 14′ with the sidewall 19, the sides of the layers 16′ and 14′ are not exposed to plasma. As a result, it is possible to restrain the deterioration of magnetic characteristics of the free ferromagnetic layer 16′ and the fixed ferromagnetic layer 14′.

Moreover, when the lower portion structure 52a of the magnetic element is formed by the etching, it is possible to form the magnetic element (the upper portion structure 51a and the lower portion structure 52a of the magnetic element) through once patterning because the sidewall 19 and the upper conductive layer 17′ are used as a mask.

Further, in the magnetic memory manufacturing method of this embodiment, as well as the first embodiment, the size of the lower portion structure 52a of the magnetic element can be controlled to about a summation of the upper portion structure 51a of the magnetic element and the thickness of the sidewall 19 (protection film 18).

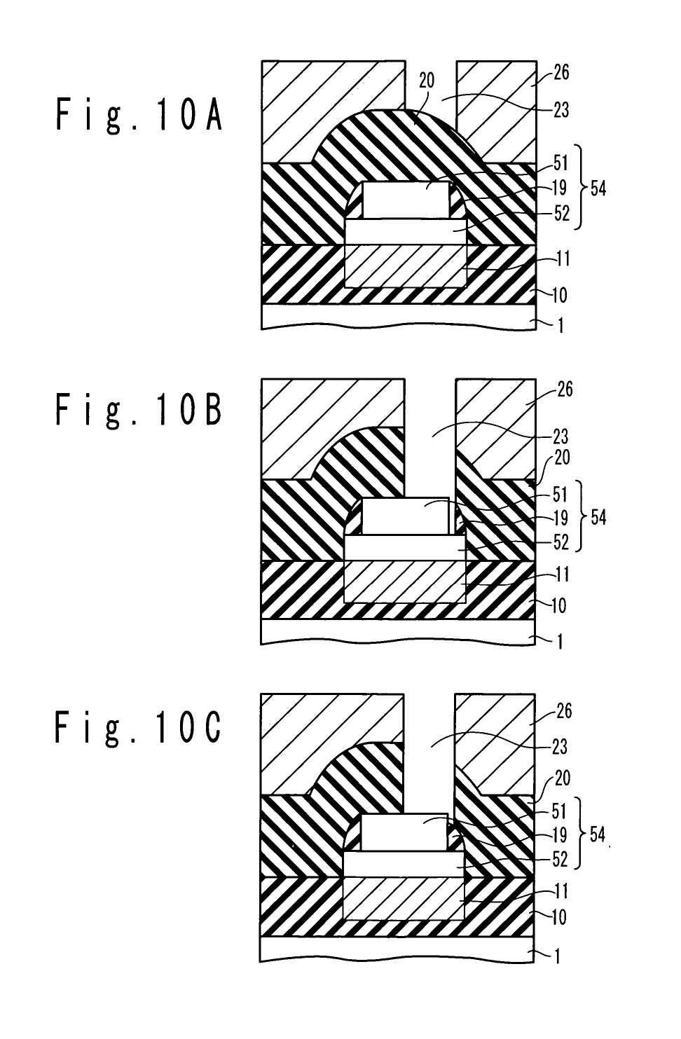

Furthermore, in the magnetic memory manufacturing method of this embodiment, because the upper wiring 21 is electrically connected with the upper conductive layer 17′, the via-hole 23 is formed at the upper portion of the interlayer insulating layer 20 by etching to form the connection with the upper wiring 21 by using the via-hole 23. In this case, by decreasing the selection ratio of the material of the sidewall 19 lower than that of the interlayer insulating layer 20, it is possible to restrain occurrence of a short-circuit and increase the production yield in the via-hole etching. This will be described below by referring to FIGS. 10A to 10C.

FIGS. 10A to 10C are cross sectional views showing steps of forming the via-hole in the interlayer insulating layer 20. These views show steps between FIGS. 3E and 3F. In this case, a case will be described in which patterning is slightly shifted.

FIG. 10A is a cross sectional view of the magnetic cell after the interlayer insulating layer 20 are formed to cover the lower insulating film 10 and the magnetic element 54 and they are patterned by using a photo-resist layer 26. In this case, when the material of the interlayer insulating layer 20 and that of the sidewall 19 are the same and the via-hole etching is carried out for a long time (deeply), not only the interlayer insulating layer 20 but also the sidewall 19 are similarly removed as shown in FIG. 10B, and the side of the magnetic element 54 appears. Then, when the upper wiring 21 is formed, a problem occurs that the magnetic element 54 is short-circuited. However, when the sidewall 19 is formed of a material having a selection ratio lower than that of the interlayer insulating layer 20, as shown FIG. 10C, a short-circuit does not occur even when the deep etching is carried out because the sidewall 19 hinders progress of etching.

It should be noted that the examples when a material having a selection ratio lower than that of the interlayer insulating layer 20 is used for the sidewall 19 are as described in the first embodiment.

Advantages described with reference to FIGS. 3E and 3F can be obtained in case of the first embodiment when a via-hole in the upper portion of the interlayer insulating layer 20 is formed by the etching and the connection with the upper wiring 21 by using the via-contact is formed in order to electrically connect the upper wiring 21 with the upper conductive layer 17′.

Moreover, in the magnetic memory manufacturing method of this embodiment, to electrically connect the upper wiring 21 with the upper conductive layer 17′, it is allowed that the interlayer insulating layer 20 is flattened by CMP and/or etching-back and the upper wiring 21 is formed on the interlayer insulating layer 20. In this case, advantages same as those described with reference to FIGS. 9A to 9C in the first embodiment can be obtained.

Furthermore, by forming a nonmagnetic film made of a conductive material which is a non-magnetic material like copper instead of the insulating film 15, the magnetic memory manufacturing method of this embodiment can be applied to formation of a GMR cell.

Furthermore, this embodiment can be modified as long as the effect of the invention is maintained.

### Third Embodiment

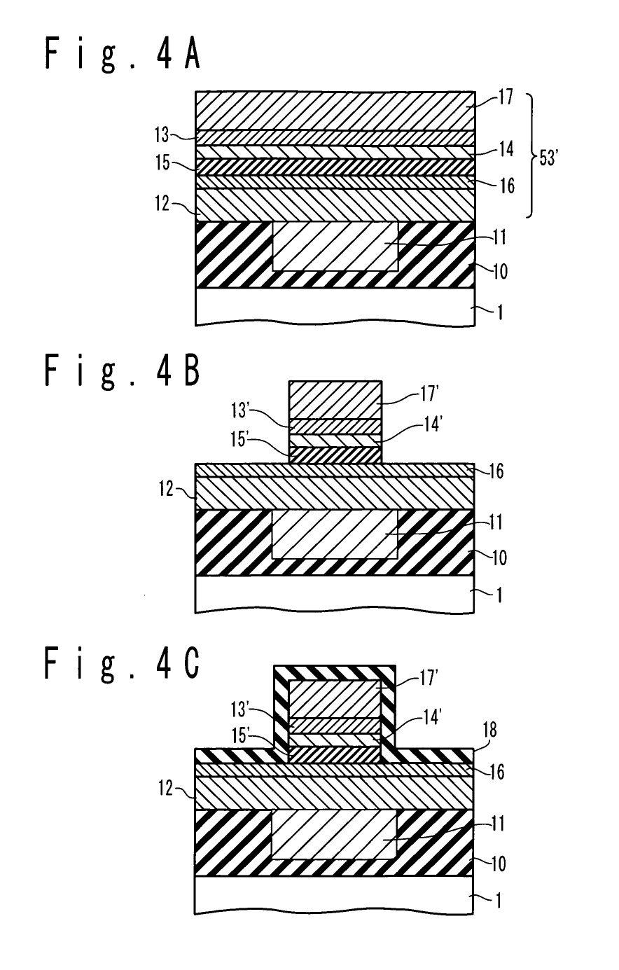

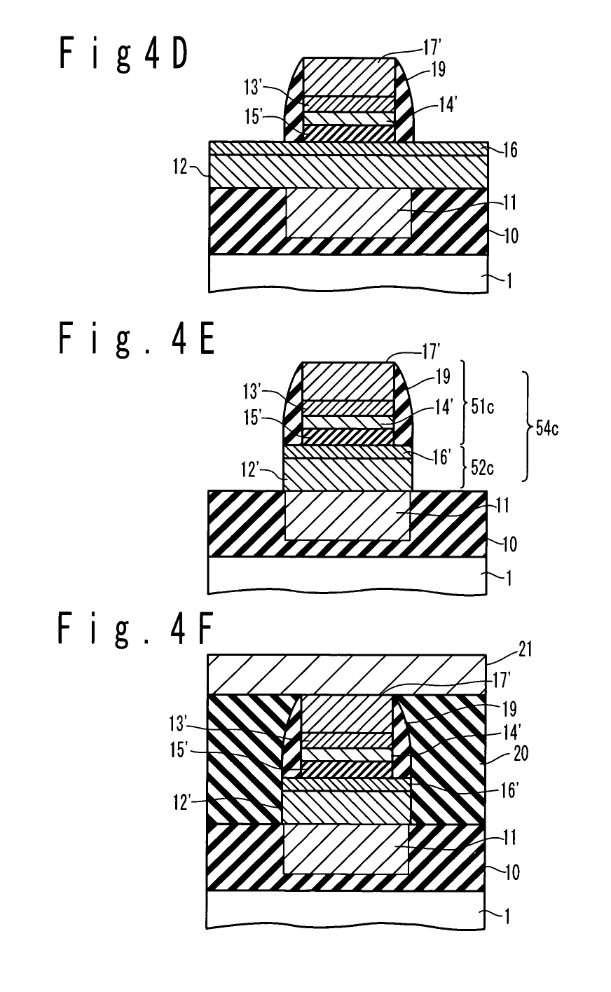

The magnetic memory and its manufacturing method according to the third embodiment of the present invention will be described below. FIGS. 4A to 4F are cross sectional views showing the magnetic memory manufacturing method in the third embodiment of the present invention. The magnetic memory manufacturing method of this embodiment is a TMR cell manufacturing method. The magnetic element serving as the TMR cell is formed on a wiring made of copper or the like which is formed on or above a CMOS circuit. FIGS. 4A to 4F show steps of manufacturing a magnetic element formed on the lower wiring 11 made of copper or the like.

First, as shown in FIG. 4A, the lower wiring 11 (e.g., copper) for write and read is formed in the lower insulating layer 10 (e.g., silicon oxide film) formed on the substrate 1 (e.g., silicon) by using the damascene process. The multi-layer film 53′ having a TMR structure is formed on the lower wiring 11. That is, a lower conductive film 12, a free ferromagnetic film 16, an insulating film 15, a fixed ferromagnetic film 14, an anti-ferromagnetic film 13, and an upper conductive film 17 are sequentially formed from the lower wiring 11 side. In this embodiment, the film forming order of the free ferromagnetic film 16, the insulating film 15, the fixed ferromagnetic film 14, the anti-ferromagnetic film 13 is opposite to that of the first embodiment. The films are the same as those of the first embodiment. However, in this embodiment, iridium manganese (IrMn) is used as the material of the anti-ferromagnetic film 13.

Next, as shown in FIG. 4B, the upper portion structure 51c of the magnetic element is formed. A photo-resist layer is patterned into the predetermined shape. Etching is carried out by an ion milling method by using the resist pattern as a mask. In this case, the etching is carried out up to the boundary between the free ferromagnetic film 16 and the insulating film 15. Subsequently, the photo-resist layer is removed. The upper conductive layer 17′, the anti-ferromagnetic layer 13′, the fixed ferromagnetic layer 14′, and insulating layer 15′ of the magnetic element are formed through the above etching. In this embodiment, the group of the upper conductive layer 17′, the anti-ferromagnetic layer 13′, the fixed ferromagnetic layer 14′, and the insulating layer 15′ is referenced to as the upper portion structure 51c of the magnetic element. The above predetermined shape is the shape of the upper portion structure 51a of the magnetic element.

Next, as shown in FIG. 4C, the sidewall 19 serving as a sidewall is formed. First, the protection film 18 is formed to cover the free ferromagnetic film 16 and the upper portion structure 51c of the magnetic element. The protection film 18 is the same as the case of the first embodiment.

Next, as shown in FIG. 4D, dry etching is applied to the protection film 18 in accordance with a predetermined condition and the sidewall 19 is formed. The predetermined condition is experimentally determined. Thereby, the sides of the upper conductive layer 17′, the anti-ferromagnetic layer 13′, the fixed ferromagnetic layer 14′ and the insulating layer 15′ are not exposed to the atmosphere of etching in the subsequent etching step. Therefore, it is possible to avoid deterioration of a film quality due to an etching gas, attachment of an etched substance to a side (side attachment), and an abnormal electrical characteristic due to the attachment.

Next, as shown in FIG. 4E, a lower portion structure 52c of the magnetic element is formed. Etching is carried out up to the bottom of the lower conductive film 12 by using the sidewall 19 and the upper conductive layer 17′ as a mask. The etching method uses ion milling. This etching is carried out up to the boundary between the lower wiring 11 and the lower conductive film 12. The free ferromagnetic layer 16′ and the lower conductive layer 12′ are formed through the above etching. In this embodiment, the free ferromagnetic layer 16′ and the lower conductive layer 12′ are also referenced to as the lower portion structure 52c of the magnetic element. Because the etching is carried out by using the sidewall 19 and the upper conductive layer 17′ as the mask, a step relating to photolithography is unnecessary. That is, although twice etchings for the upper portion structure 51a of the magnetic element and the lower portion structure 52c of the magnetic element are carried out to form the magnetic element, only once photolithography step is enough and it is possible to restrain increase of the number of steps.

Next, as shown in FIG. 4F, the interlayer insulating film 20 is formed. First, the interlayer insulating film 20 is formed to cover the lower insulating layer 10, the lower portion structure 52a of the magnetic element, and the upper portion structure 51a of the magnetic element. The interlayer insulating film 20 is the same as the case of the first embodiment. Subsequently, the upside of the interlayer insulating film 20 is polished up to the upside of the upper conductive layer 17′. In this case, the etching-back method may be used instead of the CMP method. At this time, the etching gas uses CF₄. As another method, a method of carrying out the CMP method may be first used to a middle portion and then the etching-back may be used. An upper wiring 21 is formed on the interlayer insulating film 20 as a write and read wiring.

In this way, the manufacture of a TMR cell is completed in accordance with the above steps.

In this embodiment, the formation sequence of the free ferromagnetic film 16, the insulating film 15, the fixed ferromagnetic film 14, and the anti-ferromagnetic film 13 is opposite that of the first embodiment. Therefore, in case of the magnetic element 54′, the positional relation to the free ferromagnetic layer 16′, the insulating layer 15′, the fixed ferromagnetic layer 14′, and the anti-ferromagnetic layer 13′ is opposite, compared with the magnetic element 54 of the first embodiment. However, also in case of the magnetic memory manufacturing method of this embodiment, the same advantages as those obtained from the first embodiment can be obtained.

The magnetic memory manufacturing method of this embodiment can be applied to the formation of a GMR cell by forming a nonmagnetic film of a conductive material which is a non-magnetic material like copper.

Moreover, this embodiment can be modified as illustrated in the first embodiment as long as the gist of the invention is maintained.

### Fourth Embodiment

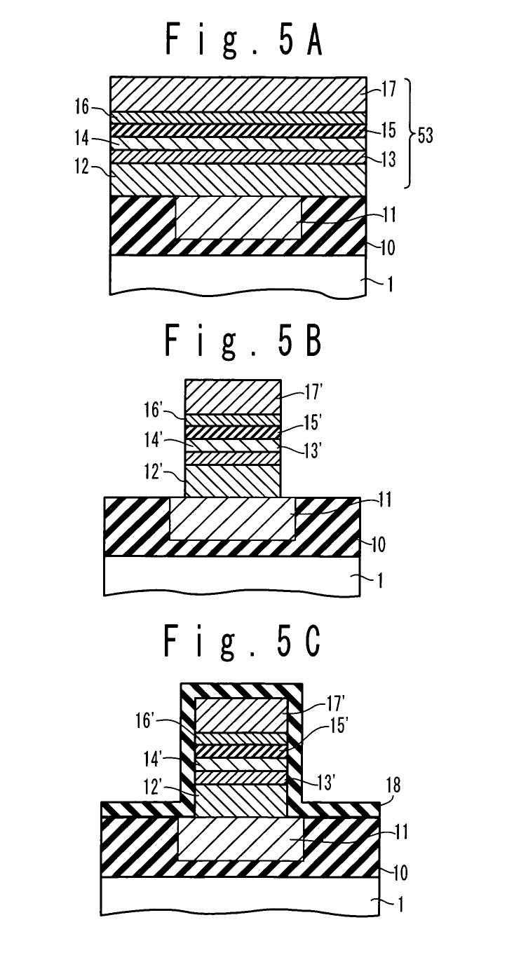

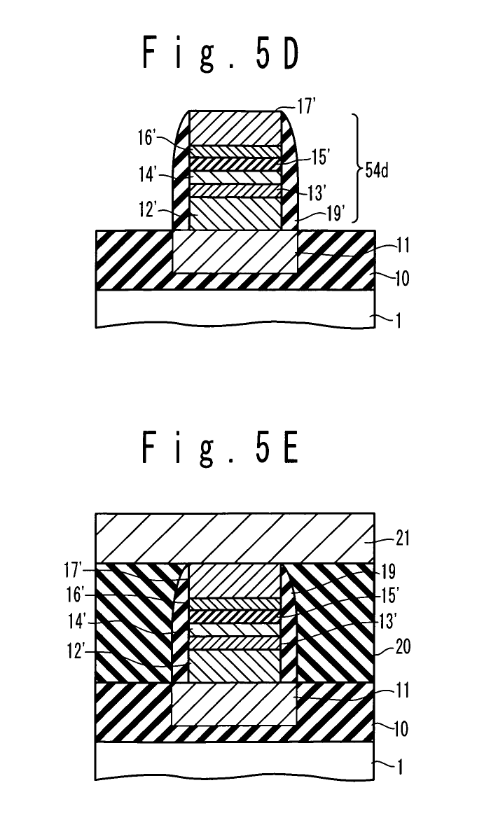

Next, the magnetic memory and its manufacturing method according to the fourth embodiment of the present invention will be described. FIGS. 5A to 5E are cross sectional views showing the fourth embodiment of the magnetic memory manufacturing method of the present invention. The magnetic memory manufacturing method of this embodiment is a TMR cell manufacturing method. A magnetic element serving as a TMR cell is formed on a wiring made of copper or the like which is formed on or above the CMOS circuit. FIGS. 5A to 5E show steps of forming the magnetic element on a lower wiring 11 made of copper or the like.

First, as shown in FIG. 5A, the lower wiring for write and read is formed in the lower insulating layer 10 (e.g., silicon oxide film) formed on the substrate 1 (e.g., silicon) by using the damascene process. A multi-layer film 53 having a TMR structure is formed on the lower wiring 11. That is, the lower conductive film 12, the anti-ferromagnetic film 13, the fixed ferromagnetic film 14, the insulating film 15, the free ferromagnetic film 16, and the upper conductive film 17 are sequentially formed from the lower wiring 11 side. The films are the same as the case of the first embodiment. In this embodiment, however, the material of the anti-ferromagnetic film 13 uses iridium manganese (IrMn).

Next, as shown in FIG. 5B, the magnetic element 54d is formed. A photo-resist layer is patterned into a predetermined shape and etching is carried out by using a resist pattern as a mask by a reactive ion etching (RIE) method. In this case, the etching is carried out up to the boundary between the lower conductive film 12 and the lower wiring 11. Subsequently, the photo-resist layer is removed. The upper conductive layer 17′, the free ferromagnetic layer 16′, the insulating layer 15′, the fixed ferromagnetic layer 14′, the anti-ferromagnetic layer 13′, and the lower conductive layer 12′ of the magnetic element are formed through the above etching. In this embodiment, the upper conductive layer 17′, the free ferromagnetic layer 16′, the insulating layer 15′, the fixed ferromagnetic layer 14′, the anti-ferromagnetic layer 13′, and the lower conductive layer 12′ are referenced to as the magnetic element 54d. The above predetermined shape is the shape of the magnetic element 54d. In this case, by decreasing the thicknesses of the films or changing etching conditions, the time of RIE is not increased.

Next, as shown in FIG. 5C, a sidewall 19 serving as a sidewall is formed. First, a protection film 18 is formed to cover the lower wiring 11 and magnetic element 54d. The protection film 18 is the same as that of the first embodiment. In this embodiment, however, an aluminum nitride film is used.

Next, as shown in FIG. 5D, the protection film 18 is dry-etched under a predetermined condition, and thereby the sidewall 19 is formed. The predetermined condition is experimentally determined. Thus, the side of the magnetic element 54d is not exposed to the atmosphere of the subsequent step. Therefore, in the free ferromagnetic layer 16′ and insulating layer 15′, it is possible to avoid deterioration of a film quality due to a subsequent step, attachment of a substance (side attachment) to a side, and an abnormal electrical characteristic due to the attachment.

Next, as shown in FIG. 5E, an interlayer insulating film 20 is formed. First, the interlayer insulating film 20 is formed to cover the lower insulating layer 10 and magnetic element 54d. The interlayer insulating film 20 is the same as those of the first embodiment. Subsequently, the upside of the layer insulting film 20 is polished up to the upside of the upper conductive layer 17′ by the chemical mechanical polishing (CMP) method. In this case, the etching-back method may be used instead of the CMP method. As another method, a method of carrying out the CMP method is first used to a middle portion and then an etching-back may be used. Then, an upper wiring 21 is formed on the interlayer insulating film 20 as a write and read wiring.

In this way, the manufacture of a TMR cell is completed in accordance with the above steps.

The magnetic memory manufacturing method of this embodiment is different from the magnetic memory manufacturing method of the second embodiment in that the number of times of etching by the RIE method is once and the upper wiring 21 is formed by the CMP (or etching-back) method. However, also in case of the magnetic memory manufacturing method of this embodiment, advantages obtained from the second embodiment can be obtained.

The magnetic memory manufacturing method of this embodiment can be applied to the manufacture of a GMR cell by forming a nonmagnetic film of a conductive material which is a non-magnetic material like copper.

Moreover, this embodiment can be modified as described in the second embodiment as long as the scope of the present invention is maintained.

### Fifth Embodiment

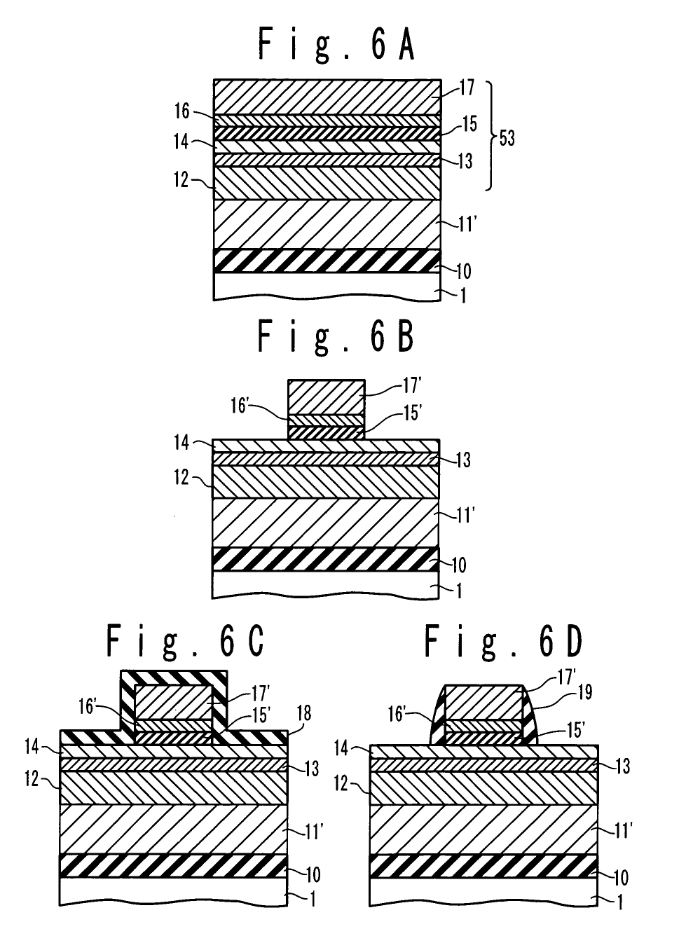

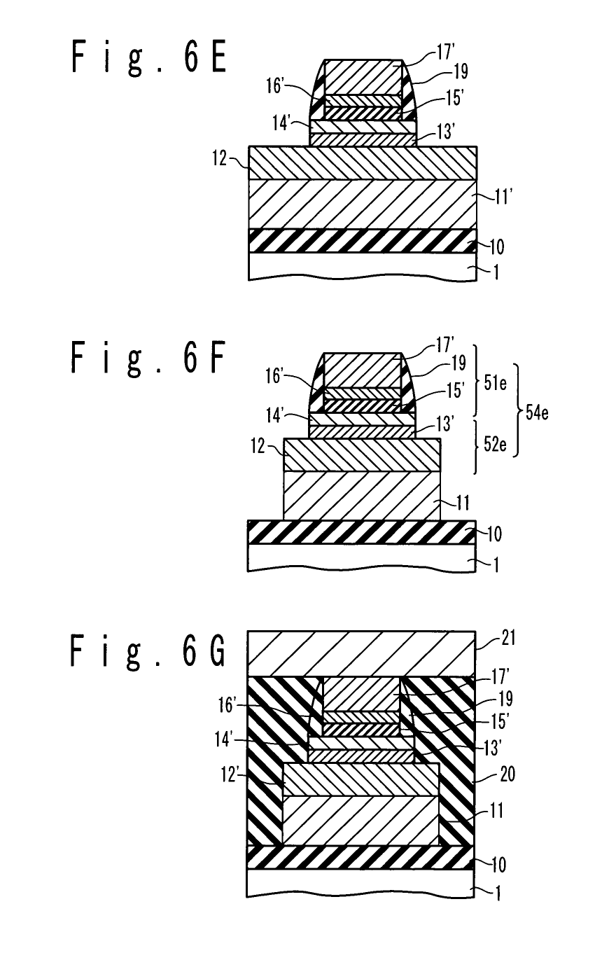

A magnetic memory and its manufacturing method according to the fifth embodiment of the present invention will be described below. FIGS. 6A to 6G are cross sectional views showing the magnetic memory manufacturing method according to the fifth embodiment of the present invention. The magnetic memory manufacturing method of this embodiment is a TMR cell manufacturing method. FIGS. 6A to 6G show steps when a magnetic element including a lower wiring 11 is formed.

First, as shown in FIG. 6A, a lower wiring layer 11′ (e.g., copper) for forming the lower write and read wiring 11 and a multi-layer film 53 having a TMR structure are formed on a lower insulating layer 10 (e.g., silicon oxide film) formed on a substrate 1 (e.g., silicon). That is, a lower wiring 11′, a lower conductive film 12, an anti-ferromagnetic film 13, an fixed ferromagnetic film 14, an insulating film 15, a free ferromagnetic film 16, and an upper conductive film 17 are sequentially formed from the lower insulating layer 10 side. The lower wiring layer 11′ may be a single layer film or multi-layer film including a conductive material like copper, aluminum, titanium, copper aluminum (AlCu), or titanium nitride. In this embodiment, the multi-layer film is formed by sequentially laminating a titanium nitride film, a titanium film, a copper aluminum film, and a titanium film. The lower conductive film 12, the anti-ferromagnetic film 13, the fixed ferromagnetic film 14, the insulating film 15, the free ferromagnetic film 16, and the upper conductive film 17 ate the same as those of the first embodiment. In this embodiment, however, the anti-ferromagnetic film 13 is formed from an iridium manganese (IrMn) film and the fixed ferromagnetic film 14 is formed from an iron cobalt (CoFe) film.

Next, as shown in FIG. 6B, an upper portion structure 51e of the magnetic element is formed. A photo-resist layer is patterned into a predetermined shape and etching is carried out by using a resist pattern as a mask by an ion milling method. In this case, the etching is carried out up to the boundary between the insulating film 15 and the fixed ferromagnetic film 14. Subsequently, the photo-resist layer is removed. An upper conductive layer 17′, a free ferromagnetic layer 16′, and an insulating layer 15′ of a magnetic element are formed through the above etching. In this embodiment, the upper conductive layer 17′, the free ferromagnetic layer 16′, and the insulating layer 15′ are referenced with the upper portion structure 51e of the magnetic element. The above predetermined shape is the shape of the upper portion structure 51e of the magnetic element.

Next, as shown in FIG. 6C, the sidewall 19 serving as a sidewall is formed. First, a protection film 18 is formed to cover the fixed ferromagnetic film 14 and upper portion structure 51e of the magnetic element. The protection film 18 is the same as that of the first embodiment.

Next, as shown in FIG. 6D, a sidewall 19 is formed by applying dry etching to the protection film 18 under a predetermined condition. The predetermined condition is experimentally determined. Thus, sides of the upper conductive layer 17′, free ferromagnetic layer 16′, and insulting layer 15′ are not exposed to the atmosphere of etching in the subsequent etching step. Therefore, in case of the free ferromagnetic layer 16′ and insulating layer 15′, it is possible to avoid deterioration of film quality due to etching gas, attachment of etched substance (side attachment) to side, and a trouble of electrical characteristic due to the attachment.

Next, as shown in FIG. 6E, a lower portion structure 52e of the magnetic element is formed. Etching is carried out up to the portion under the anti-ferromagnetic film 13 by using the sidewall 19 and the upper conductive layer 17′ as a mask. The etching method uses the ion milling method. This etching is carried out up to the boundary between the anti-ferromagnetic film 13 and the lower conductive film 12. A fixed ferromagnetic layer 14′ and anti-ferromagnetic layer 13′ are formed through the above etching.

Next, as shown in FIG. 6F, the fixed ferromagnetic layer 14′, the anti-ferromagnetic layer 13′, and the lower conductive layer 12′ are patterned into predetermined shapes by using a photo-resist layer. Etching is carried out by using a resist pattern by the ion milling method. In this case, the etching is carried out up to the boundary between the lower wiring film 11′ and the lower insulating layer 10. Subsequently, the photo-resist layer is removed. A lower conductive layer 12′ and lower wiring 11 are formed in accordance with the above etching. In this embodiment, the fixed ferromagnetic layer 14′, the anti-ferromagnetic layer 13′, and the lower conductive layer 12′ are referenced to as the lower portion structure 52e of the magnetic element. Because the etching is carried out by using the sidewall 19 and upper conductive layer 17′ as a mask, a step relating to photolithography is unnecessary. That is, although twice etchings for the upper portion structure 51a and lower portion structure 52a of the magnetic element are conventionally carried out, only once photolithography step is enough in case of the present invention. Therefore, it is possible to restrain increase of the number of steps.

Moreover, the lower wiring 11 is formed at the same time with the lower portion structure 52e of the magnetic element. That is, it is possible to omit a step of forming the lower wiring 11 by using the damascene process.

Next, as shown in FIG. 6G, an interlayer insulating film 20 is formed. First, the interlayer insulating film 20 is formed to cover the lower insulating layer 10, the lower portion structure 52e of the magnetic element, and the upper portion structure 51e of the magnetic element. The interlayer insulating film 20 is the same as that of the first embodiment. Subsequently, the upside of the layer insulting film 20 is polished up to the upper conductive layer 17′ through the chemical mechanical polishing (CMP) method. In this case, the etching-back method may be used instead of the CMP method. As another method, a method of carrying out the CMP method may be used to a middle portion and then the etching-back may be used. An upper insulating film 21 is formed on the interlayer insulating film 20 as a write and read wiring.

In this way, the manufacture of a TMR cell is completed in accordance with the above steps.

The same advantages obtained from the first embodiment can be obtained from the magnetic memory manufacturing method of this embodiment.

In case of the above embodiment, when the lower portion structure 52e of the magnetic element is formed, the fixed ferromagnetic layer 14′ and the anti-ferromagnetic layer 13′ are formed by using the sidewall 19 and the upper conductive layer 17′ as a mask, and the lower conductive layer 12′ is formed by using a photo-resist pattern as a mask. However, it is also possible to use the photo-resist pattern as a mask in an either case.

### Sixth Embodiment

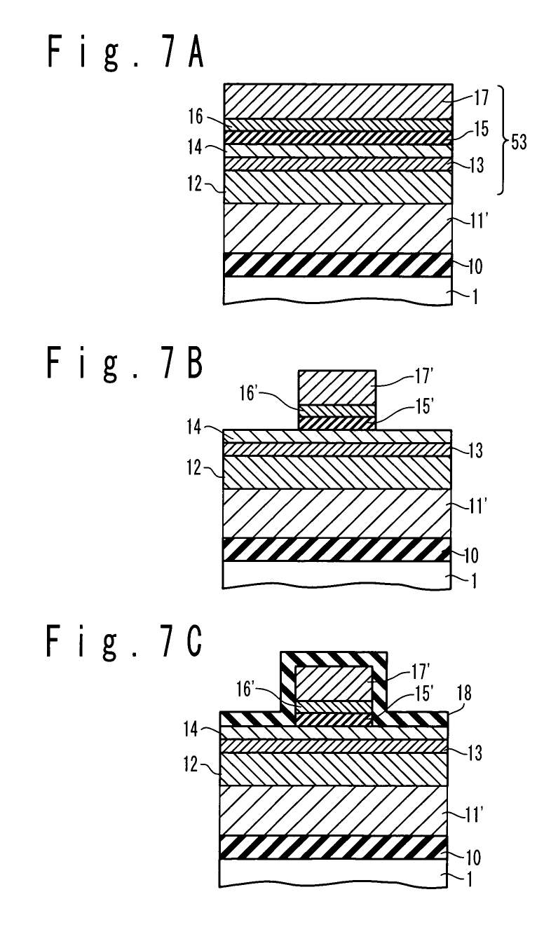

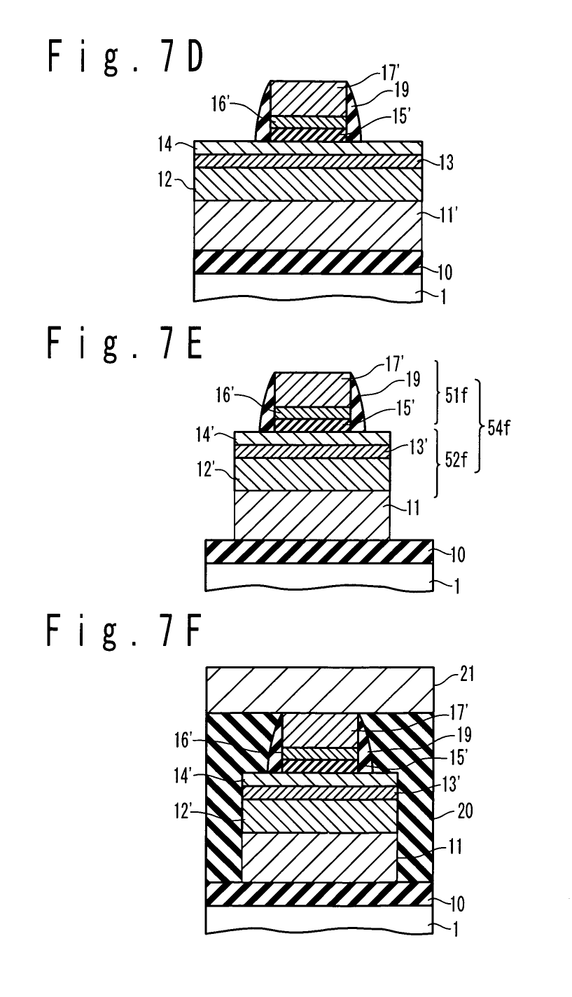

A magnetic memory and its manufacturing method according to the sixth embodiment of the present invention are described below. FIGS. 7A to 7F are cross sectional views showing the magnetic memory manufacturing method according to the sixth embodiment of the present invention. The forming steps of an upper portion structure 51f of the magnetic element (FIGS. 7A to 7D) is the same as those of the fifth embodiment shown in FIGS. 6A to 6E. However, the forming steps of a lower portion structure 52f of the magnetic element is different from that in FIG. 6F. That is, the lower portion structure 52f of the magnetic element is formed through etching by using photo-resist as a mask. Others are the same as those of the fifth embodiment. In this case, it is possible to omit the self-alignment etching process using the sidewall 19 and the upper conductive layer 17′ as a mask.

Also, it is possible to obtain the same advantages as those of the fifth embodiment.

The magnetic memory manufacturing method of this embodiment can be applied to the formation of a GMR cell by forming a nonmagnetic film made of a conductive material serving as a non-magnetic material like copper instead of insulating film 15.

Also, this embodiment can be modified as shown in the first embodiment as long as the scope of the present invention is maintained.

Moreover, the first to sixth embodiments can be applied by combining them so that they are not mutually contradicted.

It is possible to avoid a short-circuit and restrain deterioration of the magnetic characteristic of a magnetic element when the magnetic element is formed by the etching method.

1. A magnetic memory comprising:
a substrate;
a lower portion structure provided on or above said substrate as a portion of a magnetic element;
an upper portion structure provided on said lower portion structure of said magnetic element; and
a sidewall insulating film provided to surround said upper portion structure of said magnetic element.

2. The magnetic memory according to claim 1, wherein said magnetic element has a size of an outer circumference of said sidewall insulating film.

3. The magnetic memory according to claim 1, wherein said lower portion structure of said magnetic element comprises:
a conductive portion; and
a first magnetic film provided on or above said conductive portion, and
said upper portion structure of said magnetic element comprises:
an insulating film;
a second magnetic film provided on said insulating film.

4. The magnetic memory according to claim 1, wherein said lower portion structure of said magnetic element comprises a conductive portion, and
said upper portion structure of said magnetic element comprises:
a first magnetic film;
an insulating film formed on or above said first magnetic film; and
a second magnetic film provided on or above said insulating film.

5. The magnetic memory according to claim 1, wherein said upper portion structure of said magnetic element further comprise:
a conductive film formed on said second magnetic film.

6. The magnetic memory according to claim 1, wherein a plane shape of said upper portion structure of said magnetic element is any one of an oval, a cycloid, a rectangle, a hexagon, and a corner quadrangle.

7. The magnetic memory according to claim 1, wherein a distance d on a plane between an outer circumference of an upper surface of said lower portion structure of said magnetic element and an outer circumference of an upper surface of said upper portion structure of said magnetic element has a relation of 0.01 μm≦d≦0.2 μm.

8. The magnetic memory according to claim 1, further comprising:
an interlayer insulating film formed to cover said lower portion structure of said magnetic element, said sidewall insulating film, and said upper portion structure of said magnetic element,
said interlayer insulating film has a via-contact connected with said upper portion structure of said magnetic element, and
said sidewall insulating film is formed of a material which has an etching selection ratio smaller than said interlayer insulating film.

9. The magnetic memory according to claim 1, further comprising:
an interlayer insulating film formed to cover said lower portion structure of said magnetic element and said sidewall insulating film, and
said sidewall insulating film is formed of a material which has a selection ratio in a chemical mechanical polishing or an etching-back smaller than said interlayer insulating film.

10. The magnetic memory according to claim 1, wherein said sidewall insulating film is formed of at least one of metal nitride, metal oxide, and metal carbide.

11. The magnetic memory according to claim 1, wherein said sidewall insulating film comprises at least one of silicon oxide, silicon nitride, aluminum oxide, and aluminum nitride.

12. A method of manufacturing a
magnetic memory comprising:
forming a multi-layer film included in a magnetic element on or above a substrate;
etching said multi-layer film into a predetermined pattern up to a predetermined depth, to form an upper portion structure of said magnetic element;
forming a sidewall insulating film to surround said upper portion structure of said magnetic element;
etching a remaining portion of said multi-layer film by using said sidewall insulting film and said upper portion structure of said magnetic element as a mask to form a lower portion structure of said magnetic element.

13. The method according to claim 12, wherein said forming a multi-layer comprises:
forming a conductive film and a first magnetic layer formed on or above said conductive film in a portion corresponding to said lower portion structure of said magnetic element;
forming an insulting layer and a second magnetic layer formed on or above said insulating layer in a portion corresponding to said upper portion structure of said magnetic element.

14. The method according to claim 12, wherein said etching said multi-layer film into a predetermined pattern, comprises:
etching said multi-layer film into said predetermined pattern by using a physical etching.

15. The method according to claim 14, wherein said physical etching is ion milling.

16. The method according to claim 12, wherein said forming a multi-layer comprises:
forming a conductive film in a portion corresponding to said lower portion structure of said magnetic element; and
forming
a first magnetic layer; an insulating layer formed on or above said first magnetic layer; and a second magnetic layer formed on or above said insulating layer in a portion corresponding to said upper portion structure of said magnetic element.

17. The method according to claim 16, wherein each of said etching a remaining portion of said multi-layer film is carried out by using a physical and chemical etching.

18. The method according to claim 16, wherein said physical and chemical etching is a reactive ion etching.

19. The method according to claim 12, further comprising:
forming an interlayer insulating film to cover said lower portion structure of said magnetic element, said sidewall insulating film, and said upper portion structure of said magnetic element; and
forming a via-hole in said interlayer insulating film so as to be connected with said upper portion structure of said magnetic element by an etching method,
said sidewall insulating film is formed of a material which has an etching selection ratio smaller than said interlayer insulating film.

20. The method according to claim 12, further comprising:
forming an interlayer insulating film to cover said lower portion structure of said magnetic element, said sidewall insulating film, and said upper portion structure of said magnetic element; and
flattening said interlayer insulating film on said upper portion structure of said magnetic element by a chemical mechanical polishing method or an etching-back method,
said sidewall insulating film is formed of a material which has a selection ratio in the chemical mechanical polishing method or the etching-back method smaller than said interlayer insulating film.
